(19) United States
(12) Patent Application Publication
(10) Pub. No.: US 2026/0354456 A1
(43) Pub. Date: Nov. 12, 2026

(54) Inhalation Device

(71) Applicant: JT International SA, Geneva (CH)

(72) Inventors: Akira Yamaguchi, Geneva (CH); Ryo Hasegawa, Geneva (CH); Tom Hamilton, London (GB); Norihiko Inoue, London (GB); Jamie Buckley, Ditton (GB)

(73) Assignee: JT International SA, Geneva (CH)

(21) Appl. No.: 19/135,268

(22) PCT Filed: Dec. 7, 2023
(86) PCT No.: PCT/EP2023/084670

§ 371 Date: Jun. 3, 2025

(30) Foreign Application Priority Data
Dec. 8, 2022 (EP) 22212224.4

(51) Int. Cl. A24F 40/40

(52) U.S. Cl. CPC A24F 40/40

(57) ABSTRACT

An inhalation device includes a body with a recess for receiving a consumable, a displaceable cover having an opening, a slidable spring carrier for covering the recess and carrying a spring, and a base provided on the body and having a track accommodating a first arm portion of the spring. The track has a locking portion adapted to lock the spring in a position, in which the spring carrier covers the recess. The cover, when being displaced, is adapted to move the spring carrier, when in the position covering the recess, so as to disengage the spring from the locking portion, and is adapted to move the spring carrier, when in the position exposing the recess, so as to engage the spring with the locking portion.

### TECHNICAL FIELD

The present invention relates to an inhalation device such as a device for heating a consumable like a tobacco stick.

### TECHNICAL BACKGROUND

Several types of inhalation or aerosol generating devices are known and continuously replace traditional cigarettes. Such devices usually have a body with a recess for receiving a consumable, such as a stick having an aerosol generating substance, which may comprise tobacco. Before and after use it is generally desirable to cover the recess.

In this context, for example, KR 102355185 B1 is related to a device as described above having a slidable cover for covering a recess, which is adapted to receive a consumable. Further, somewhat similar devices are known from EP 2 727 619 B1 and EP 2 531 053 B1.

### SUMMARY OF THE INVENTION

It is an object underlying the invention to provide an inhalation device of the above-mentioned type with a particularly user-friendly mechanism for opening and closing the recess.

This is achieved by the inhalation devices described in claims 1 and 15.

Accordingly, the device has a body with a recess for receiving a consumable and a slidable spring carrier for covering the recess and carrying a spring. Moreover, a displaceable cover having an opening is provided, and a base is provided on the body of the cover having a track accommodating a first arm of the above-mentioned spring. The track further has a locking portion adapted to lock the spring in a position in which the spring carrier covers the recess, and the cover, when being displaced, is adapted to move the spring carrier, when in the position covering the recess, so as to disengage the spring from the locking portion, and is further adapted to move the spring carrier, when in the position exposing the recess, so as to engage the spring with the locking portion.

This essentially allows the cover to move in one and the same direction for both closing and opening the recess, similar to the operation of a click pen, i.e. movement of an actuator in one and the same direction alternatively exposing and retracting the tip of the pen. This provides, with regard to the inhalation device described herein, an easy operation by the user, since, as described, repeated movement of the cover in one and the same direction alternatively opens and closes the recess. This is essentially achieved by, starting from a position, in which the spring carrier covers the recess, and its spring being locked in the locking portion of the track, disengaging the spring from the locking portion which moves the spring carrier in a position exposing the recess.

Moreover, the cover then also moves into a position, in which its opening is aligned with the recess, so as to allow the insertion of a consumable, such as a heatable stick. After inhaling and removing the consumable, displacement of the cover in the same direction, as it was moved for exposing the recess, will engage the spring provided on the spring carrier with the locking portion, so that the spring carrier will cover the recess. As will be detailed below, the novel mechanism can be provided efficiently, so that also with regard to the costs, the user experience is good.

Preferred embodiments are described in the further claims.

The spring carrier is preferably biased into the position exposing the recess, which advantageously interacts with the cover moving the spring carrier, when in the position covering the recess, so as to disengage the spring from the locking portion. Due to the spring carrier being biased, it will then automatically move into the position exposing the recess.

Particularly the outer appearance of the device can be improved, and, in use, a seamless device can advantageously be provided, if the cover is biased into a position, in which it is at least partially flush with the body.

In order to guide the cover during its above-described movements, it is beneficial to provide the cover with a cover portion and a frame portion. The cover portion will typically cover the recess, and the frame portion will be used for guiding the movement.

In particular, it has proven beneficial to guide the cover, in particular its frame portion by the base.

Since the spring is in any case provided with a first arm portion accommodated in the track, the spring can efficiently be provided with a second arm portion biasing the spring carrier.

In order to provide an overall nice appearance of the device, also during movement of the various components, the spring carrier preferably has a spring cover, which particularly covers the spring.

As regards suitable materials for the various components, it is currently preferred and will provide beneficial properties to the mentioned components, when the cover, in particular the cover portion thereof, and the spring are made of metal. In contrast, one or more of the frame portion, the spring cover, the spring carrier and the base can efficiently be made from plastic.

Whereas also a differing mechanism is generally possible, it provides advantages with regard to the mechanism enabling the above-described movements of the various components, when the cover and the spring carrier are movable along the same direction.

Whereas the recess and the cover covering same can generally be provided anywhere on the device as a whole, it provides a well-designed device, when the body is elongate, and the cover is displaceable in a direction substantially perpendicular to the longitudinal axis of the body. In other words, the body will typically have two surface areas perpendicular to the longitudinal axis thereof, which are significantly smaller than the remaining, typically four surface areas parallel to the longitudinal axis, and the cover preferably covers the recess provided on one of the described smaller surface areas and typically extending substantially along the longitudinal axis.

As regards the detailed design of the spring, it is currently preferred and allows efficient production of the spring, when the first and second arm portion thereof are on opposite sides of a spiral portion of the spring.

As detailed above, the inhalation device described herein allows the displacement of the cover for moving the spring carrier when it is in the position covering the recess to be in the same direction as displacement of the cover for moving the spring carrier, when it is in the position exposing the recess. This provides a pleasant user experience.

Finally, it further improves the user experience, when the displacement of the cover both for exposing and covering the recess has the same amount. In other words, the user will easily get used to a displacement amount, which is advantageously the same for both exposing and covering the recess.

### BRIEF DESCRIPTION OF THE DRAWINGS

An embodiment of the invention will be described in more detail below with reference to the accompanying drawings, in which

FIG. 1 shows an exploded perspective view of essential parts of the inhalation device,

FIG. 2 shows a sectional view of the parts shown in FIG. 1,

FIGS. 3 to 8 show, in a top view including a detail thereof, the operations for exposing and covering the recess of the device, and

FIGS. 9 to 14 show the device as a whole in a top and a side view during the operations shown in FIGS. 3 to 8.

### DETAILED DESCRIPTION OF AN EMBODIMENT

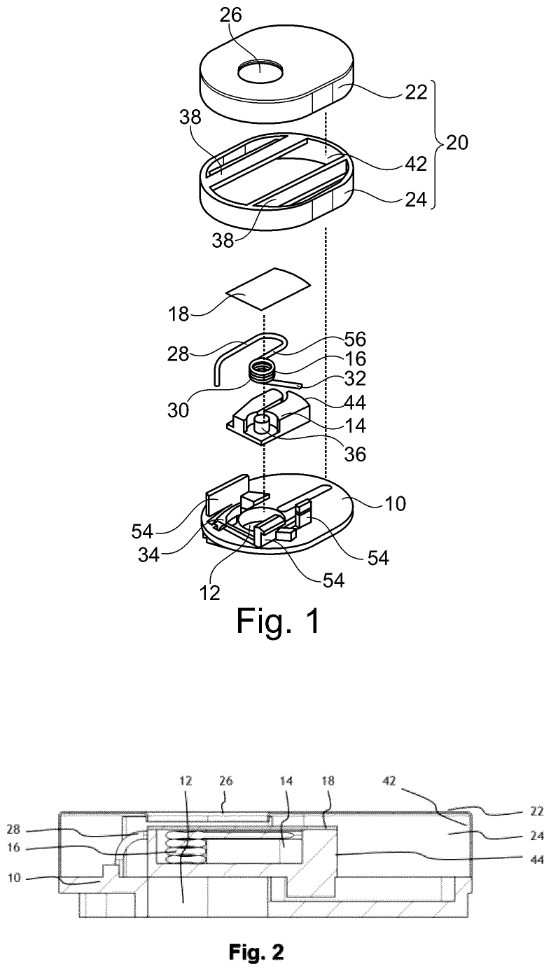

As shown in FIG. 1, the mechanism of the device for opening and closing the recess thereof, as visible in FIGS. 5, 6, 11 and 12, has a base 10 with an opening 12 which at least substantially coincides with the recess of the device for receiving a consumable as described below. A spring carrier 14 carrying a spring 16 and capable of covering the opening 12 of the base 10 is slidable on the base 10 in an essentially horizontal direction of FIG. 2. Moreover, a cover 18 is provided so as to cover the spring 16.

Further, a cover 20 having a cover portion 22 and a frame portion 24 is also provided slidable with regard to the base 10. As can be seen in the drawing, the cover 20 has an opening 26, which is, in use, essentially aligned with the opening 12 of the base 10. As can also be seen in both FIG. 1 and FIG. 2, the spring 16 is typically a spiral spring with a spiral portion 30, a first arm portion 28 and a second arm portion 32. In the embodiment shown, the first arm portion 28 is essentially U-shaped and has an end bent essentially 90° from the plane of the U so as to interact with a track 34 provided on the base 10 as detailed below.

The second arm portion 32 also interacts with a suitable structure on the base 10 so as to bias the spring carrier into the position exposing the recess as well as the opening 12 of the base 10.

The spring carrier 14 has a pin 36, which is, in the assembled state, accommodated in the center of the spiral portion 30 of the spring 16. Further, the leg 56 of the spring 16 connecting the first arm portion 28 to the spiral portion 30 via the U is accommodated in a groove between blocks formed on the spring carrier 14. The spring cover 18 is essentially flat, and the base 10 as well as the cover including its cover portion 22 and its frame portion 24 are essentially, in a top view, oval with rounded ends and essentially straight portions between the ends. The frame portion 24 of the cover 20 is reinforced by longitudinal strips 38 essentially extending horizontal in the orientation shown in FIG. 2 and essentially parallel to the sides of the cover 20. The sidewalls of the frame portion 24 and the reinforcing strips 38 can advantageously cooperate with suitable structures provided on the base, such as walls 54 so as to guide the cover 20 during the movements for opening and closing the recess. Also the spring carrier 14 is suitably guided by the base 10.

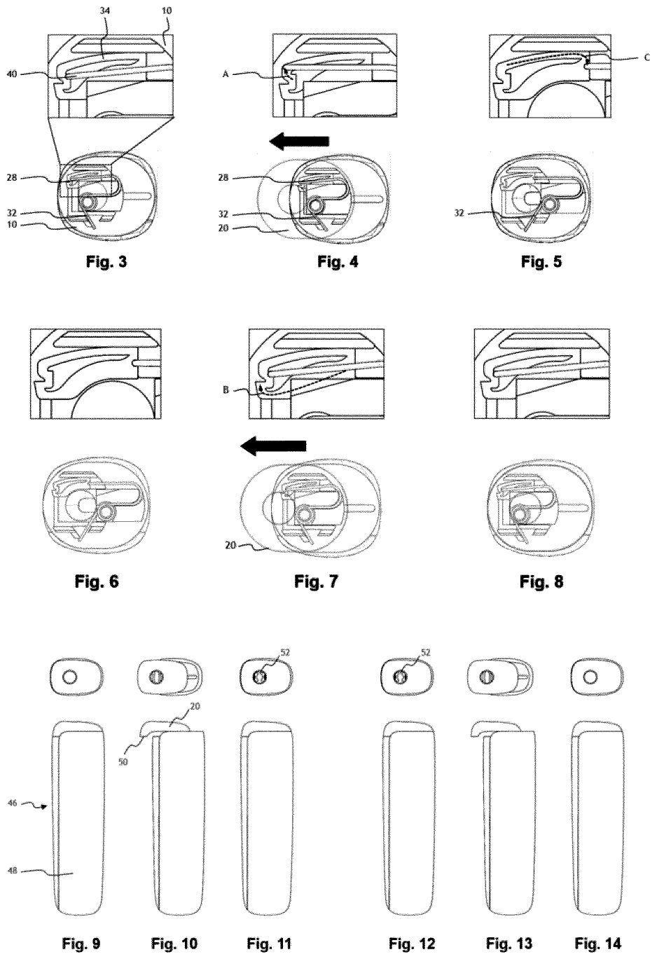

Operation of the mechanism so as to open and close the recess of the device, will be explained by starting from the closed state as shown both in FIG. 2 and FIG. 3. In this state, the first arm portion 28 of the spring engages a locking portion 40 of the track 34 provided on the base 10. Moving the cover 20 to the left as shown in FIG. 4, will also, towards the end of the movement of the cover, move the spring carrier 14 somewhat to the left, since the inner face of the cover denoted 42 in FIGS. 1 and 2 will abut the opposing face 44 of the spring carrier 14, so that the cover 20 will, after the mentioned abutting, move the spring carrier 14 including the spring 16 thereon sufficiently to the left as shown in FIG. 4, so that the first arm portion 28 of the spring 16 will disengage from the locking portion 40 as indicated by arrow A. Generally, as additionally indicated by arrow C in FIG. 5, the track 34 has an upper part slightly inclined towards the outside of the device, i.e. towards the upper part in FIGS. 3 to 8, when viewed from left to right in these figures. As will be detailed below, the lower part of the track 34 is inclined in the same way and leads to the locking portion 40, where the first arm portion 28 is located in the state shown in FIG. 3.

As can be seen in FIGS. 3 and 4, the second arm portion 32 engages a suitable structure on the base 10 so as to bias the spring carrier towards the right in FIGS. 3 to 8. As can be seen in FIG. 5, as soon as the first arm portion 28 is unlocked, the pretension in the second arm portion 32 pushes the spring carrier 14 to the right, and as a consequence, the spring 16 is relaxed. The cover 20 will then, preferably also by means of suitable biasing, be moved to the position shown in FIG. 5, that is essentially flush with the body of the device.

As can particularly be seen in FIG. 6, in the state exposing the recess, the above-described inner face 42 of the cover 20 and the opposing face 44 of the spring carrier 14 are already in contact in this state. Starting from this position, exposing the recess and as shown in FIG. 6, movement of the cover 20 to the left will again, due to the above-mentioned abutment, move the spring carrier 14 to the left so as to cover the recess and move the first arm portion 28 of the spring in the track 34, now the lower part thereof according to the figures, and as indicated by the arrow B, to the locking portion 40 so as to lock the spring 16 and keep the spring carrier 14 in the position covering the recess as shown in FIG. 7. Finally, and as shown in FIG. 8, the cover 20 can then again be moved in the position corresponding to that of FIGS. 5 and 3. In summary, the spring locking/unlocking with the track contributes to the spring carrier's positioning so as to cover or expose the recess and allows movement of the spring carrier between these positions.

The remaining figures essentially show the above-described operations for the entire device 46. It will particularly be appreciated, that its body 48 is essentially elongate with a longitudinal axis in a vertical direction of the lower part of FIGS. 9 to 14. As can be taken from the upper part of each of the mentioned figures showing a top view, the top and bottom surface is substantively smaller than the side surfaces, one of which can be seen in the lower part of FIGS. 9 to 14. In the embodiment shown, the cover 20 is further designed with an extension 50 extending from an otherwise essentially flat bottom of the cover 20 towards the body 48 so as to provide a stop for movement of the cover 20 to the right according to the figures, and so as to indicate to the user, that the cover is only movable to the left according to the figures.

The cover 20 has, as can be seen in the lower part of each of FIGS. 9 to 14, a height along the longitudinal axis, which is significantly smaller than that of the device 46. In particular, at the side opposite the extension 50, the right side in the figures, the cover 20 makes up for about one half of the rounded edge at this upper side of the device 46. At the side of the extension 50, the extension makes up for the entire curve at this edge. Generally, the device 46 has the appearance of a cuboid with rounded edges so as to provide a pleasant feeling when handled, and significantly smaller upper and lower sides according to the lower part of FIGS. 9 to 14. Further, in the embodiment shown, the side facing the viewer in the lower part of FIGS. 9 to 14 is somewhat larger than the right and left sides according to the figures. In the undisplaced position of the cover 20 as shown in FIGS. 9, 11, 12 and 14, the cover 20 is essentially flush with the entire body 48 of the device so as to provide a seamless appearance. It can further be taken from FIGS. 10 and 13, that movement of the cover 20 both for opening and for closing the recess 52, which is particularly shown in FIGS. 11 and 12, is in the same direction and has the same amount both for opening and closing the recess 52. Finally, in the embodiment shown, the recess 52 is located eccentrically in the left and right direction of FIGS. 9 to 14 and approximately centered in the up-and-down direction of the top part of these figures. In this direction, the recess covers about 30 to 50% of the cover, and in the left and right direction of these figures about 25 to 35%.

1. An inhalation device comprising:
a body with a recess for receiving a consumable,
a displaceable cover having an opening
a slidable spring carrier for covering the recess and carrying a spring, and
a base provided on the body and having a track accommodating a first arm portion of the spring,
the track having a locking portion adapted to lock the spring in a position, in which the spring carrier covers the recess,
the cover when being displaced,
being adapted to move the spring carrier when in the position covering the recess so as to disengage the spring from the locking portion and
being adapted to move the spring carrier when in a position exposing the recess so as to engage the spring with the locking portion.

2. The inhalation device of claim 1, wherein the spring carrier is biased into the position exposing the recess.

3. The inhalation device of claim 1, wherein the cover is biased into a position at least partially flush with the body.

4. The inhalation device of claim 1, wherein the cover has a cover portion and a frame portion.

5. The inhalation device of claim 1, wherein the cover is guided by the base.

6. The inhalation device of claim 1, wherein the spring has a second arm portion biasing the spring carrier.

7. The inhalation device of claim 1, wherein the spring carrier has a spring cover.

8. The inhalation device of claim 1, wherein the cover and/or the spring are made of metal.

9. The inhalation device of claim 4, wherein at least one of the frame portion, a spring cover of the spring carrier, the spring carrier and the base are made of plastic.

10. The inhalation device of claim 1, wherein the cover and the spring carrier are movable along the same direction.

11. The inhalation device of claim 1, wherein the body is elongate and the cover is displaceable in a direction substantially perpendicular to the a longitudinal axis of the body.

12. The inhalation device of claim 6, wherein the first and second arm portion are on opposite sides of a spiral portion of the spring.

13. The inhalation device of claim 1, wherein displacement of the cover for moving the spring carrier, when the spring carrier is in the position covering the recess, is in the same direction as displacement of the cover for moving the spring carrier, when it the spring carrier is in the position exposing the recess.

14. The inhalation device of claim 1, wherein displacement of the cover for moving the spring carrier, when the spring carrier is in the position covering the recess, is of the same amount as displacement of the cover for moving the spring carrier when it the spring carrier is in the position exposing the recess

15. The inhalation device of claim 1, wherein repeated displacement of the cover in the same direction alternately exposes and covers the recess by the spring carrier.

16. The inhalation device of claim 4, wherein the frame portion is guided by the base.

17. The inhalation device of claim 4, wherein the cover portion and/or the spring are made of metal.
